(19) United States
(12) Patent Application Publication
(10) Pub. No.: US 2006/0197573 A1
(43) Pub. Date: Sep. 7, 2006

(54) Semiconductor integrated circuit and method for manufacturing semiconductor integrated circuit

(76) Inventors: Yoichi Matsumura, Takatsuki-shi (JP); Takako Ohashi, Otsu-shi (JP); Fumihiro Kimura, Nara-shi (JP); Kiyohito Mukai, Souraku-gun (JP); Masanori Itou, Takatsuki-shi (JP)

Correspondence Address: MCDERMOTT WILL & EMERY LLP, 600 13TH STREET, N.W., WASHINGTON, DC, 20005-3096, US

(21) Appl. No.: 11/365,604

(22) Filed: Mar. 2, 2006

(30) Foreign Application Priority Data
Mar. 2, 2005 (JP) 2005-057687

(51) Int. Cl. G06F 1/04; H03K 3/00

(52) U.S. Cl. 327/291; 365/201

(57) ABSTRACT

The semiconductor integrated circuit of the present invention comprises a clock circuit for generating a clock signal. The clock circuit comprises a clock control circuit for controlling propagation of the clock signal. The clock control circuit comprises a burn-in control signal input terminal for inputting a burn-in control signal that controls operation state of the clock circuit when performing burn-in processing, and a clock control signal output terminal for outputting the clock signal. The clock control circuit controls propagation of the clock signal outputted from the clock control signal output terminal based on the burn-in control signal inputted to the burn-in control signal input terminal.

### BACKGROUND OF THE INVENTION

1. Field of the Invention

The present invention relates to a semiconductor integrated circuit that supplies and controls clock signals and to a method for manufacturing the semiconductor integrated circuit.

2. Description of the Related Art

Most of semiconductor integrated circuits containing logic circuits operate by synchronizing with clock signals supplied from outside or clock signals generated inside thereof based on signals supplied form outside. In general, a semiconductor integrated circuit comprises a plurality of flip-flops and a circuit for (referred to as a clock circuit hereinafter) which generates clock signals to be supplied to each flip-flop based on supplied clock signals. In order for the semiconductor integrated circuit to operate properly, it is necessary to supply the clock signals properly to each flip-flop.

Further, in order to reduce power consumption of the semiconductor integrated circuit, it is effective to stop supply of the clock signal for the circuit block that is not to be in action. Thus, there are inserted circuits (clock control circuits) in the clock circuit for stopping supply of the clock signals. The semiconductor integrated circuit is so designed that a section where propagation of the clock signal is stopped changes by switching the clock control circuits for each operation mode.

Furthermore, in accordance with advanced micronization of the semiconductor integrated circuits, size of transistors constituting logic cells contained in the clock circuit have been reduced. Thus, delay time fluctuation due to aging deterioration cannot be ignored.

The aging deterioration of the transistor exhibits a large fluctuation at an initial stage, and the fluctuation amount decreases thereafter. Thus, while the transistor is set in action (gate is ON, low potential for the case of P-channel transistor and high potential for the case of N-channel transistor), burn-in processing (abbreviated as BI processing hereinafter) is performed for deteriorating the transistor before actual use. Such deterioration processing performed before actual use is referred to as advance deterioration hereinafter.

By deteriorating each transistor in advance, fluctuation due to the aging deterioration thereafter becomes insignificant. By checking the circuit action in this state and then shipping it as a product, troubles due to aging deterioration to be happened on the market can be prevented.

However, in order to achieve low power consumption of the semiconductor integrated circuit, the number of the clock control circuits to be inserted has become great and the structure thereof has become complicated. As a result, it is difficult to form an operation mode for propagating the clock signals to all the paths within the clock circuit. Thus, when the BI processing is performed under the state where the clock signal is not propagated, sufficient advance-deterioration processing cannot be performed on a section where the transistor is not in action (gate is OFF). As a result, the product on the market, which is action-tested under the state where there still remains the transistor without sufficient advance-deterioration processing performed by the BI processing, may deteriorate over time due to actual operation and generate a large delay time fluctuation. Therefore, there may cause failure when used by a user.

In order to perform sufficient BI processing for the case of complicated circuit, the BI processing may be performed for each of a plurality of operation modes. By performing the BI processing for each of the plurality of operation modes, the PI processing can be performed while all the transistors within the clock circuit are in action. However, there generate other problems, i.e. an increase in the time for performing the BI processing and an increase in the inspection cost.

For those problems, Japanese Patent Unexamined Publication (6-325597) discloses a method for applying stress for shortening the time for performing the BI processing of the memory circuit through transmitting boosted signals to gate oxide films of all the memory-cell transistors within a chip.

The conventional method as described is a method that applies stress for each memory cell lined in array like the memory circuit through multiple-selection of word lines that are directly connected to each memory cell by BI signals. However, there is no such signal lines like the word lines directly connected to each cell in a random logic such as a clock signal, in which a buffer, inverter, clock control circuit, etc. are in serial-connection. Therefore, this method is not applicable. Furthermore, when the BI signal is connected to each cell as in the conventional case, wirings for connection becomes enormous. Thus, it is not practical. Moreover, the conventional method supplies stress to each cell by changing row address lines, so that it requires the time for processing, which is proportional to the number of the row address lines.

### SUMMARY OF THE INVENTION

The main object of the present invention therefore is to perform BI processing (advance deterioration) uniformly on all the transistors without increasing the processing time and the wirings.

In order to achieve the aforementioned object, the semiconductor integrated circuit of the present invention comprises a clock circuit for generating a clock signal. The clock circuit comprises a clock control circuit for controlling propagation of the clock signal. The clock control circuit comprises a burn-in control signal input terminal for inputting a burn-in control signal that controls operation state of the clock circuit when performing burn-in processing, and a clock control signal output terminal for outputting the clock signal. The clock control circuit controls propagation of the clock signal outputted from the clock control signal output terminal based on the burn-in control signal inputted to the burn-in control signal input terminal.

A typical example of the semiconductor integrated circuit manufacturing method according to the present invention comprises the steps of: preparing a plurality of clock control circuits which comprise a burn-in control signal input terminal for inputting a burn-in control signal that controls operation state when performing burn-in processing, and a clock control signal output terminal for outputting the clock signal; and connecting the plurality of clock control circuits successively on a circuit by repeating processing, which is to connect the burn-in control signal output terminal of one of the plurality of clock control circuits to the burn-in control signal input terminal of another circuit.

In the semiconductor integrated circuit and the semiconductor integrated circuit manufacturing method of the present invention, propagation of the clock signal in the clock control signal output terminal of the clock control circuit is controlled by inputting the burn-in control signal to the burn-in control signal input terminal of the clock control circuit. With this, all the transistors can be advance-deteriorated. Also, one-time processing allows the transistors to be advance-deteriorated, thus increasing no processing time. Furthermore, the burn-in control signal input terminal and the wiring are added only to the clock control circuit, so that an increase of the wiring can be suppressed.

Moreover, by changing the signal-fixed direction, all the transistors can be advance-deteriorated without increasing the processing time and the wirings. Also, one-time processing allows the transistors to be advance-deteriorated, thus increasing no processing time.

Furthermore, with the semiconductor integrated circuit and the semiconductor integrated circuit manufacturing method of the present invention, all the transistors in the clock circuit that supplies and controls the clock signals can be advance-deteriorated without increasing the processing time and the wirings.

### BRIEF DESCRIPTION OF THE DRAWINGS

Other objects of the present invention will become clear from the following description of the preferred embodiments and the appended claims. Those skilled in the art will appreciate that there are many other advantages of the present invention possible by embodying the present invention.

FIG. 1 is a block diagram of a typical clock control circuit to which a first embodiment of the present invention is applied;

FIG. 2 is a block diagram of conventional transistors which achieve the clock control circuit of FIG. 1;

FIG. 3 is a block diagram of a clock circuit that comprises clock control circuits with BI control signal input terminal according to the first embodiment;

FIG. 4 is a block diagram of a clock circuit that comprises the clock control circuits with BI control signal input terminal according to the first embodiment;

FIG. 5 is a block diagram of the clock control circuit with BI control signal input terminal according to the first embodiment;

FIG. 6 is a block diagram of the clock control circuit with BI control signal input terminal according to the first embodiment;

FIG. 7 is a block diagram of the clock control circuit with BI control signal input terminal according to the first embodiment;

FIG. 8 is a truth table of the clock control circuit with BI control signal input terminal according to the first embodiment;

FIG. 9 is a truth table of a clock control circuit with BI control signal input terminal according to a modification of the first embodiment;

FIG. 10 is a block diagram of a clock circuit that comprises the clock control circuits with BI control signal input terminal;

FIG. 11 is a block diagram of the clock control circuit with BI control signal input terminal according to a second embodiment;

FIG. 12 is a block diagram of the clock control circuit with BI control signal input terminal according to the second embodiment;

FIG. 13 is a block diagram of the clock control circuit with BI control signal input terminal according to the second embodiment;

FIG. 14 is a truth table of the clock control circuit with BI control signal input terminal according to the second embodiment;

FIG. 15 is a block diagram of a clock circuit that comprises the clock control circuits with BI control signal input terminal according to the second embodiment;

FIG. 16 is a flowchart for showing the procedure of a chain-type connecting method according to the second embodiment;

FIG. 17 is a flowchart for showing the procedure of the chain-type connecting method according to the second embodiment;

FIG. 18 is a block diagram of a clock circuit that comprises the clock control circuits with BI control signal input terminal according to a modification of the second embodiment;

FIG. 19 is an illustration for describing a manufacturing method according to a third embodiment, which provides the control circuit with BI control signal provided in a part of the clock circuit;

FIG. 20 is an illustration for describing a manufacturing method according to the third embodiment, which provides the clock control circuit with BI control signal provided in a part of the clock circuit;

FIG. 21 is a block diagram of a clock circuit that comprises the clock control circuit;

FIG. 22 is a block diagram of a clock circuit that comprises a clock control circuit;

FIG. 23 is a flowchart for showing the procedure for changing the clock control circuit according to a fourth embodiment;

FIG. 24 is a block diagram of a clock circuit that comprises the clock control circuits according to the fourth embodiment;

FIG. 25 is a block diagram of a clock circuit that comprises the clock control circuits according to the fourth embodiment;

FIG. 26 is a block diagram of a clock circuit that comprises the clock control circuits;

FIG. 27 is a block diagram of a clock circuit that comprises the clock control circuits according to a fifth embodiment;

FIG. 28 is a flowchart for showing the procedure of a method for decreasing replacement-required sections according to a sixth embodiment;

FIG. 29 is a block diagram of a clock circuit that comprises the clock control circuits according to the sixth embodiment;

FIG. 30 is a block diagram of a clock circuit that comprises the clock control circuits according to the sixth embodiment;

FIG. 31 is an illustration for describing antenna damages of the transistor according to the sixth embodiment; and

FIG. 32 is an illustration for describing antenna damages of the transistor according to the sixth embodiment.

### DETAILED DESCRIPTION OF THE INVENTION

Preferred embodiments of the present invention will be described hereinafter by referring to the accompanying drawings.

### FIRST EMBODIMENT

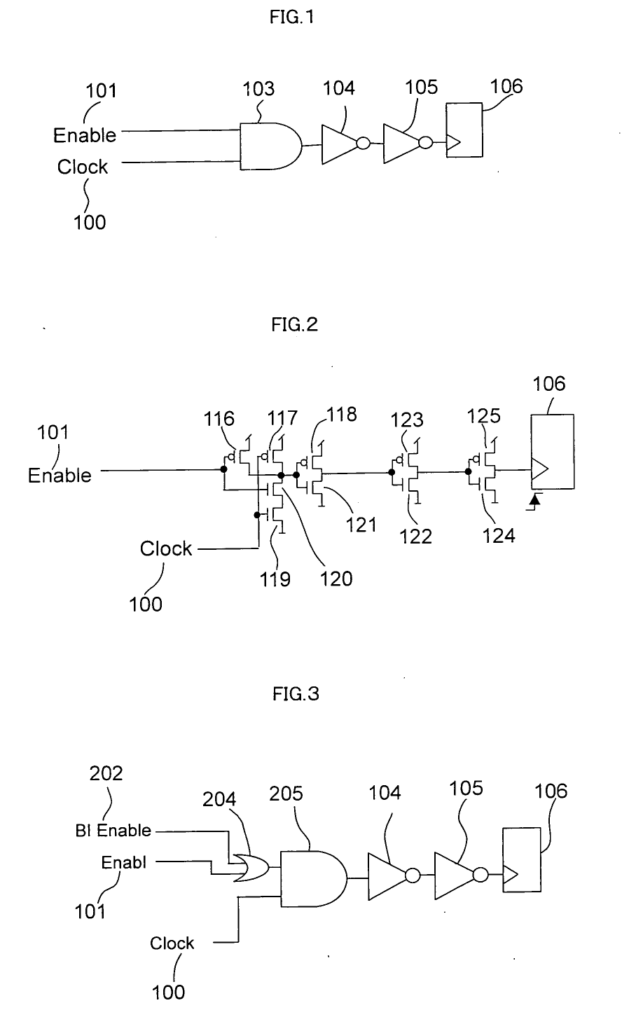

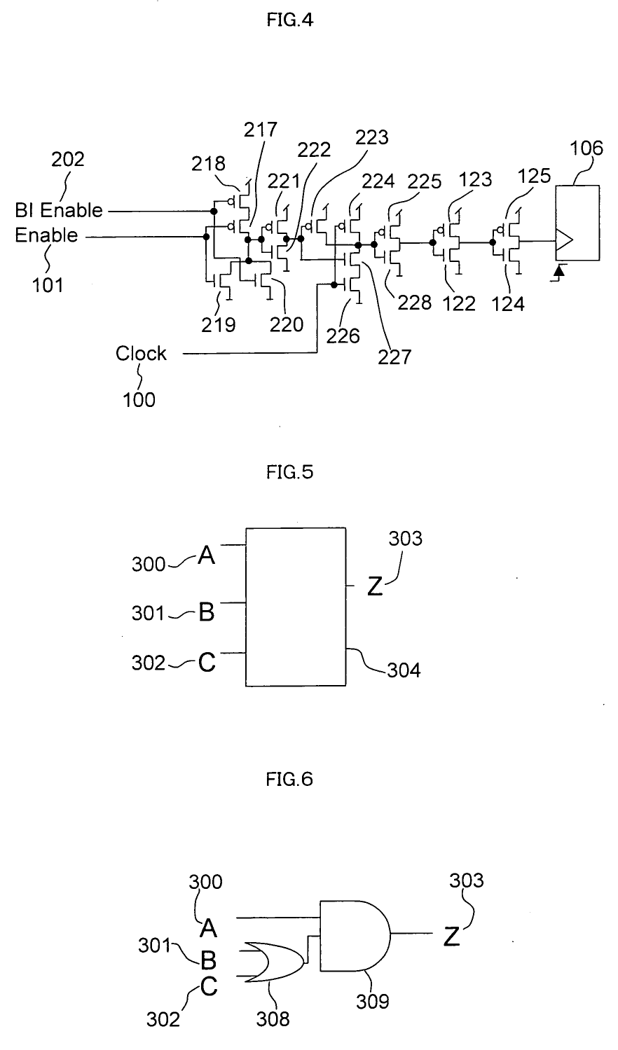

A first embodiment of the present invention will be described by referring to FIG. 1-FIG. 9. FIG. 1 is a block diagram for showing a typical example of a clock circuit that comprises clock control circuits. FIG. 2 is a block diagram (circuit diagram) of conventional transistors which achieve the clock control circuit of FIG. 1. FIG. 3 is a block diagram for showing the structure of the clock circuit according to the embodiment, which comprises the clock control circuits with BI control signal input terminal. FIG. 4 is a block diagram (circuit diagram) of transistors according to the embodiment, which achieve the clock control circuit of FIG. 3. FIG. 5-FIG. 9 are illustrations for describing the clock control circuit with BI control signal input terminal according to the embodiment.

In FIG. 1, reference numeral 100 is a clock signal, 101 is a clock control signal, 103 is an AND circuit, 104, 105 are inverter circuits, 106 is a rise signal action flip-flop.

FIG. 2 is an illustration where the AND circuit 103 and the inverter circuits 104, 105 are illustrated with transistors. Reference numeral 116-121 are the transistors that constitute the AND circuit 103, 122 and 123 are the transistors that constitute the inverter circuit 104, and 124 and 125 are the transistors that constitute the inverter circuit 105, respectively.

FIG. 3 shows a circuit in which the AND circuit of FIG. 1 is replaced with an OR circuit and an AND circuit. Reference numeral 202 is a BI control signal, 204 is the OR circuit, and 205 is the AND circuit.

FIG. 4 is an illustration where the OR circuit 204, 205 and the inverter circuits 104, 105 of FIG. 3 are illustrated with transistors. Reference numeral 217-222 are the transistors that constitute the OR circuit 204, and 223-228 are the transistors that constitute the AND circuit 205.

In FIG. 5, reference numeral 304 is a clock control circuit with BI control signal input terminal, 300 is a clock signal terminal (A), 301 is a clock control signal input terminal (B), 302 is a BI control signal input terminal (C), and 303 is a clock control signal output terminal (Z), respectively.

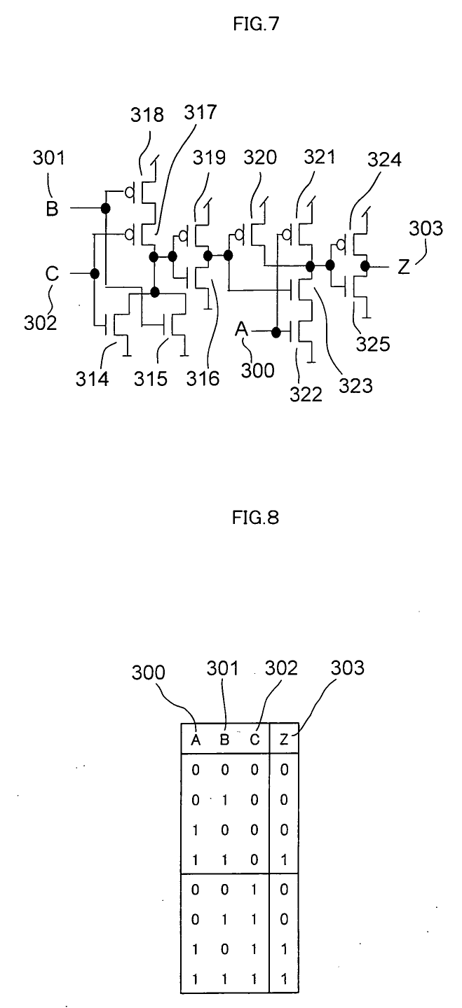

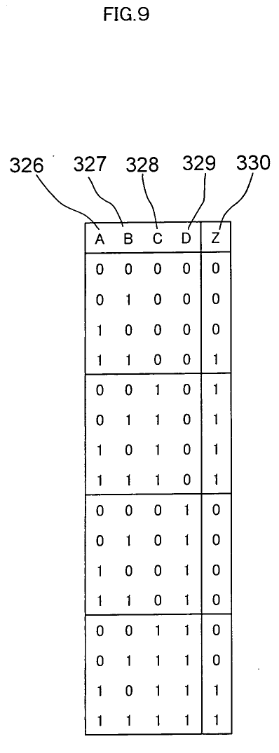

FIG. 6 is a circuit showing the internal logic of FIG. 5, in which reference numeral 308 is an OR circuit, and 309 is an AND circuit, respectively. FIG. 7 is an illustration where the OR circuit 308 and the AND circuit 209 of FIG. 6 are illustrated with transistors. Reference numeral 314-319 are the transistors that constitute the OR circuit 308, and 320-325 are the transistors that constitute the AND circuit 309. FIG. 8 shows a truth table of a control circuit 304 with BI control signal input terminal. FIG. 9 shows a truth table of a control circuit with BI control signal input terminal as a modification. In FIG. 9, reference numeral 326 is a clock signal terminal (A), 327 is a clock control signal input terminal (B), 328, 329 are BI control signal input terminals (C), (D), and 330 is a clock control signal output terminal (Z), respectively.

In the circuit of FIG. 1, when supply of the clock signal to the rise signal action flip-flop 106 is stopped (supply of the clock signal is stopped thereafter), by making the clock control signal 101 as low potential, an output signal of the AND circuit 103 is fixed as low. Thus, action of the rise signal action flip-flop 106 stops. As a result, the transistors 123 and 124 turn to be the transistors that operate when the supply of the clock signal is stopped (hereinafter, referred to as a clock-signal non-supplied-state operating transistor).

In the meantime, when the clock signal to the rise signal action flip-flop 106 is supplied, by making the clock control signal 101 as high potential, waveform of the clock signal 100 propagates to an output signal of the AND circuit 103. As a result, the transistors (hereinafter, referred to as a flip-flop driven-state operating transistor) which operate when the rise signal action flip-flop 106 obtains data are the transistors 119, 120, 118, 122, and 125.

Particularly, after the AND circuit 103, the clock-signal non-supplied-state operating transistors 123, 124 and the flip-flop driven-state operating transistors 122, 125 differ. Thus, when the BI processing is performed while the AND circuit 103 is under the state where supply of the clock signal is stopped, the flip-flop driven-state operating transistors 122, 125 cannot be advance-deteriorated. As a result, in the clock circuit connected to the rise signal action flip-flop 106, the transistors 122 and 125, after being on the market, may face aging deterioration when the clock circuit is in action, and the circuit may malfunction.

Thus, the AND circuit 103 is replaced with the clock control circuit 304 with BI control signal input terminal. As shown in FIG. 5, the clock control circuit 304 with BI control signal input terminal is so constituted that control of the BI control signal input terminal (C) 302 allows propagation of a signal of the clock signal terminal (A) 300 to the clock control signal output terminal (Z) 303. FIG. 6 is an example of the internal logic of the clock control circuit 304 with BI control signal input terminal. By setting the BI control signal input terminal (C) 302 as high potential, the signal of the clock signal terminal (A) 300 propagates to the clock control signal output terminal (Z) 303.

FIG. 3 is a clock circuit using the clock control circuit 304 with BI control signal input terminal (see FIG. 5). In order to allow easy comprehension of the connection of the clock circuit with BI control signal input terminal, it is illustrated as in the structure (the OR circuit 204, the AND circuit 205) of FIG. 6.

When supply of the clock signal to the rise signal action flip-flop 106 in the clock circuit of FIG. 3 is stopped, if the clock control signal 101 is set as low potential, the output signal of the AND circuit is fixed as low. Thus, supply of the clock signal to the rise signal action flip-flop 106 is stopped, and the transistor 123, 124 of FIG. 4 turn to be the clock-signal non-supplied-state operating transistors. However, by setting not only the potential of the clock signal 101 but also the BI control signal 202 as high potential, the transistors 122, 125, which are the same as the flip-flop driven-state operating transistors, come in action. Therefore, an operation mode for setting the BI control signal 202 as high potential (referred to as BI mode hereinafter) is formed. As a result, by performing the BI processing using the formed BI mode, the flip-flop driven-state operating transistors 122 and 125 can be fully advance-deteriorated before being on the market.

As described above, in the semiconductor integrated circuit to which the clock control circuit 304 with BI control signal input terminal is mounted, the flip-flop driven-state operating transistors 122 and 125 can be advance-deteriorated even under the state where supply of the clock signal is stopped. Thereby, all the transistors can be advance-deteriorated without causing any increase in the processing time and the wirings.

The above-described structure of the clock control circuit 304 with BI control signal input terminal is merely an example. In this case, as shown in FIG. 6, there is only one pin of the BI control signal input terminal (C) 302 being set and, as shown in FIG. 8, the signal inputted from the clock signal terminal (A) 300 is outputted from the clock control signal output terminal (Z) when the BI control signal input terminal (C) 302 is of high potential. However, as shown in FIG. 9, after setting a plurality of pins of the BI control signal input terminals (BI control signal input terminal (C) 328, BI control signal input terminal (D) 329)), any of the following controls may be carried out. From the clock control signal input terminal (Z):
high potential is constantly outputted
low potential is constantly outputted
waveform inputted from the clock signal terminal (A) is outputted

Furthermore, regardless of the structures and conditions, any of the following controls may be carried out. The output of the clock control signal output terminal (Z) 330 is set:
as high potential constantly
as low potential constantly
to perform only one action of the waveform inputted from the clock signal terminal (A)

As described above, by setting the state of the output terminal elective from high potential, low potential, or the output of the clock signal waveform, any transistors can be advance-deteriorated. Specifically, constant output of the high potential from the clock control circuit with BI control signal input terminal allows supply of continuous electric charge to P-channel-type transistors that affect the drive of the rise signal action flip-flop. Thus, it is possible to promote advance-deterioration of the P-channel-type transistors within a short period.

Furthermore, constant output of the low potential from the clock control circuit with BI control signal input terminal allows supply of continuous electric charge to N-channel-type transistors that affect the drive of the fall signal action flip-flop. Thus, it is possible to promote advance-deterioration of the N-channel-type transistors within a short period.

Moreover, constant output of the clock waveform from the clock control circuit with BI control signal input terminal allows advance-deterioration of the P-channel-type and N-channel-type transistors to the same extent as that of the clock circuit which has no clock control circuit inserted therein.

### SECOND EMBODIMENT

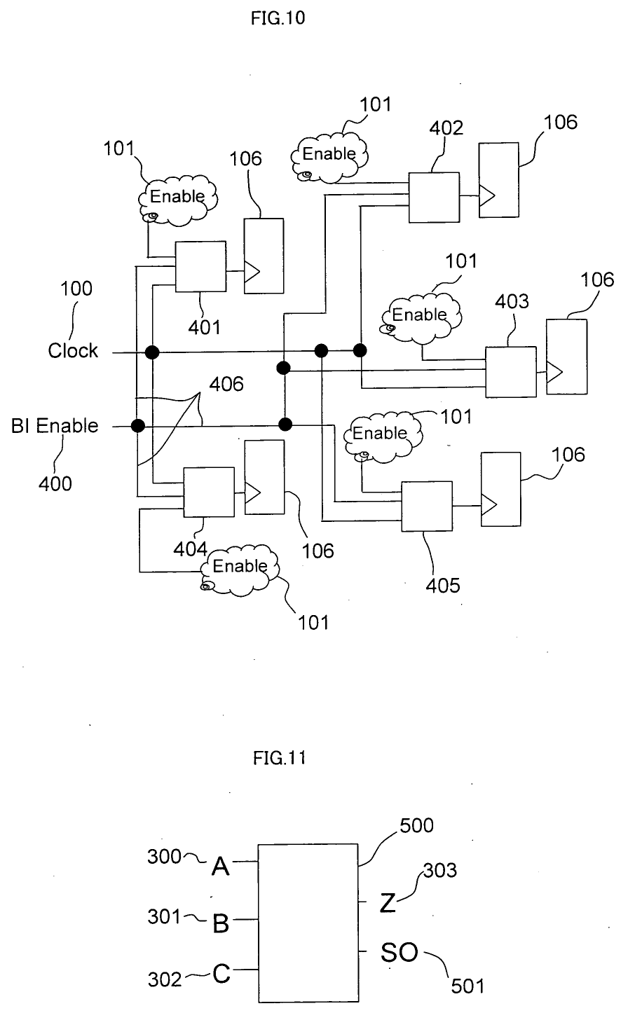

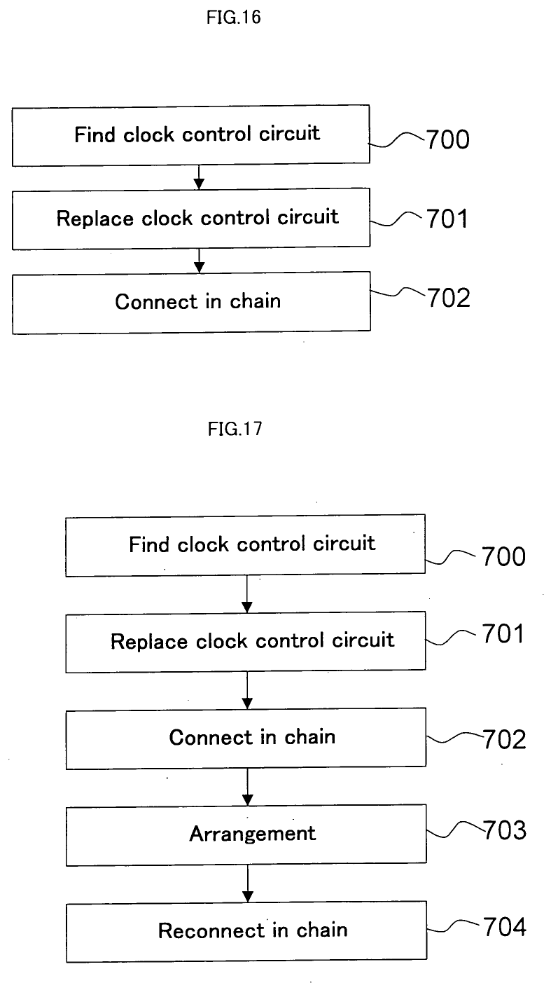

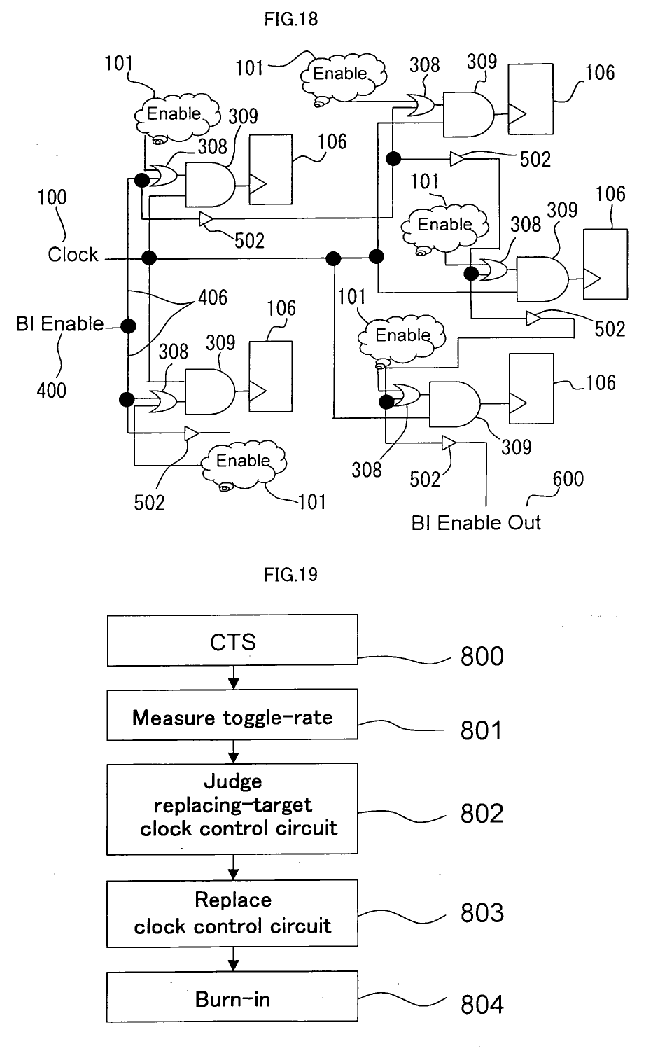

A second embodiment of the present invention will be described by referring to FIG. 10-FIG. 18. The same reference numerals are applied to the same structural elements as those of the first embodiment, and the description thereof will be omitted. FIG. 10 is a block diagram for showing an example the clock circuit that comprises a clock control circuit with BI control signal input terminal. FIG. 11-FIG. 14 are illustration for describing the clock control circuit with BI control signal input/output terminal of this embodiment. FIG. 15 is a block diagram showing another example of the clock circuit that comprises a clock control circuit with BI control signal input/output terminal. FIG. 16 and FIG. 17 are flowcharts for showing the procedures of a chain-type connecting method. FIG. 18 is a block diagram for showing a modification of the clock circuit of the embodiment, which comprises a clock control circuit with BI control signal input/output terminal.

In FIG. 10, reference numeral 400 is a BI control signal, 401-405 are clock control circuits with BI control signal input terminal, and 406 is the wiring. In FIG. 11, reference numeral 500 is a clock control circuit with BI control signal input/output terminal and 501 is a BI control signal output terminal (SO).

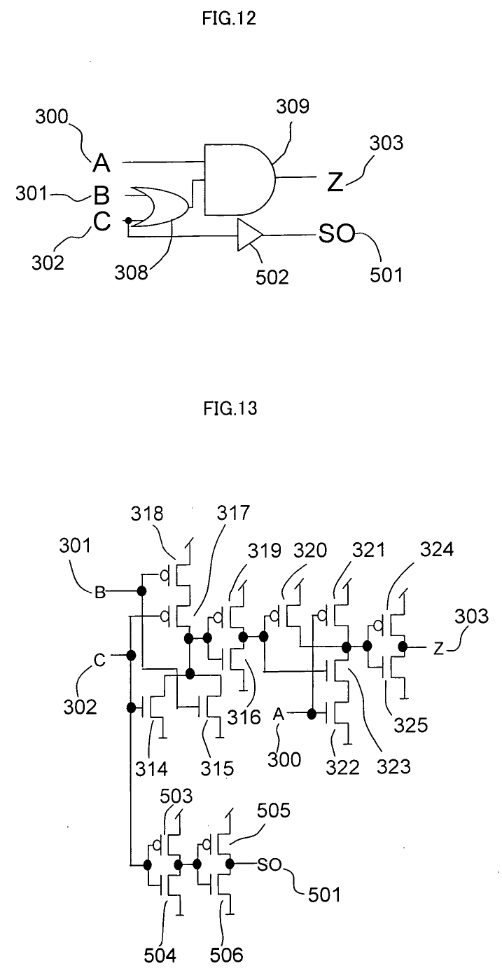

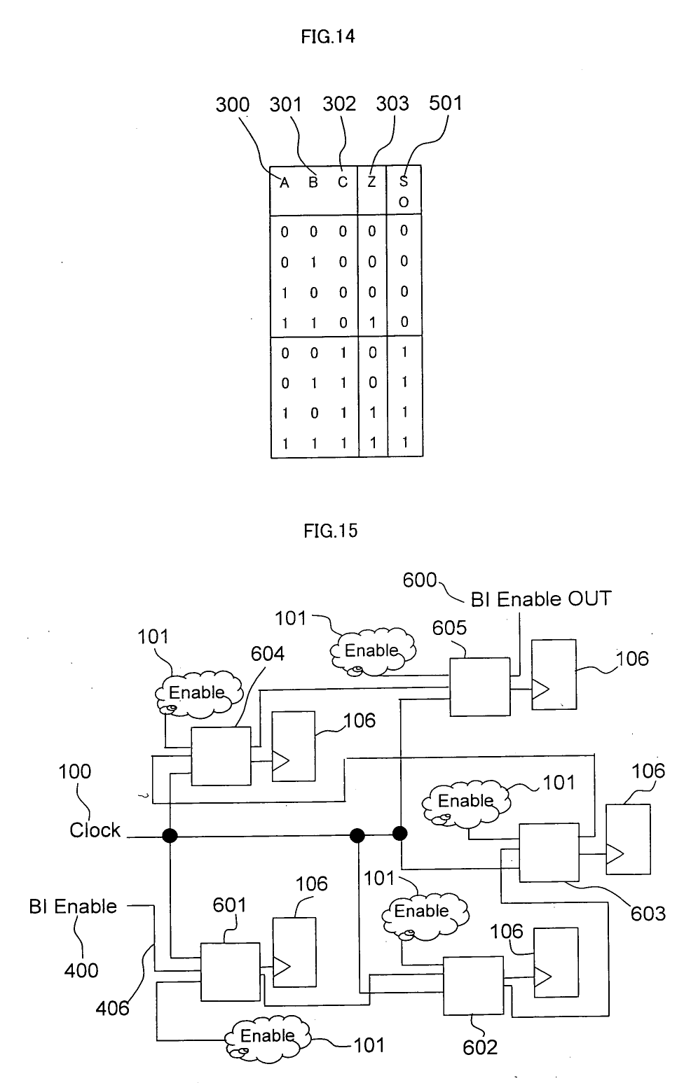

FIG. 12 is a circuit for showing the internal logic of FIG. 11, in which reference numeral 502 is a buffer circuit. FIG. 13 is an illustration where the OR circuit 308, the AND circuit 309 and the buffer circuit 502 are illustrated with transistors. Reference numerals 503-506 are the transistors constituting the buffer circuit 502. FIG. 14 shows a truth table of the clock control circuit 500 with BI control signal input/output terminal. In FIG. 15, reference numeral 600 is an output part of the BI control signal and 601-605 are the clock control circuits with BI control signal input/output terminal. In FIG. 16, reference numeral 700 is a step of finding the clock control circuit, 701 is a step of replacing the clock control circuit, and 702 is a step of chain connection. In FIG. 17, reference numeral 703 is an arranging step, and 704 is a step of chain reconnection.

The clock circuit shown in FIG. 10 has the structure designed such that all the clock control circuits on the clock circuit are the clock control circuits 304 with BI control signal input terminal (see FIG. 5). With this structure, when all the BI control signal input terminals (C) of the OR circuit constituting the clock control circuits 401-405 with BI control signal input terminal are connected to the input part of the BI control signal 400 (such connection is referred to as one-point-concentrated connection hereinafter), there generates congestion of the wiring 406 locally in the vicinity of the input part of the BI control signal 400.

In order to overcome such congestion of the wiring, in the embodiment, the clock control circuits 304 with BI control signal input terminal are replaced with the clock control circuits 500 with BI control signal input/output terminal shown in FIG. 11.

FIG. 12 is an example of the internal logic of the clock control circuit 500 with BI control signal input/output terminal (FIG. 11), in which, compared to the structure shown in FIG. 6, the BI control signal output terminal (SO) 501 for propagating the signal value of the BI control signal input terminal (C) 302 and the buffer circuit 502 are additionally provided.

In the clock circuit comprising the clock control circuits 500 with BI control signal input/output terminal (FIG. 11, FIG. 12), an arbitrary circuit 500 is selected from a plurality of clock control circuits 500 with BI control signal input/output terminal, and the input part of the BI control signal 400 is connected to the BI control signal input terminal (C) 302 of the selected circuit 500. Then, the BI control signal input terminal (C) 302 of one of the remaining circuits 500 is connected to the BI control signal output terminal (SO) 501 of the circuit 500 that is connected to the input part of the BI control signal 400 and, further, the BI control signal input terminal (C) 302 of one of the remaining circuits 500 is connected to the BI control signal output terminal (SO) 501 of the circuit 500. By repeating such connection described above, all the clock control circuits 500 with BI control signal input/output terminal 500 on the clock circuit are connected in order. Such connection is referred to as chain connection hereinafter.

FIG. 15 shows the case where the chain-connected clock control circuits with BI control signal input/output terminal 500 as described above are disposed for all of the clock control circuits 601-605 with BI control signal input/output terminal. In FIG. 15, the input part of the BI control signal 400 in the semiconductor integrated circuit is connected only to the BI control signal input terminal (C) of the clock control circuit 601 with BI control signal input/output terminal, which is propagated to the clock control circuits 602-605 with BI control signal input/output terminal in order. Thus, it is possible to avoid having congestion of the wiring 406 locally in the vicinity of the input part of the BI control signal 400 as in the case of the one-point-concentrated connection.

The input part of the BI control signal 400 in the semiconductor integrated circuit, along with the clock control circuits 500 with BI control signal input/output terminal, is designed to be disposed on the semiconductor integrated circuit in advance. Further, the BI control signal 400 is a signal for sufficiently advance-deteriorating the transistors. Thus, there is no restriction in the transmission speed thereof so that there is no problem caused by chain-connection in terms of the signal transmission speed.

Next, there is described the method of chain-connecting the clock control circuits 500 with BI control signal input/output terminal in the clock circuit by referring to FIG. 16. First, the clock control circuits (including the clock control circuits with BI control signal input terminal) are searched and found on the clock circuit (clock control circuit finding step 700).

Then, the clock control circuits or the clock control circuits 304 with BI control signal input terminal 304 on the clock circuit, which are found in the step 700, are replaced with the clock control circuits 500 with BI control signal input/output terminal (clock control circuit replacing step 701).

Subsequently, in the chain connecting step 702, the control signal input terminals (C) 302 of each clock control circuit 500 with BI control signal input/output terminal and the BI control signal output terminal (SO) 501 are chain-connected in order (chain connecting step 702).

When replacing with the clock control circuits 500 with BI control signal input/output terminal in the clock control replacing step 701, there are prepared and replaced with the clock control circuits 500 with BI control signal input/output terminal 500 having the same delay value, respectively, as that of the clock control circuits as the target of replacement. Thereby, generation of clock skew due to the replacement can be suppressed.

However, in the procedure shown in FIG. 16, the input part of the BI control signal 400, the control signal input terminals (C) 302, and the BI control signal output terminal (SO) 501 are not connected in accordance with the coordinates of the arrangement of the clock control circuits 500 with BI control signal input/output terminal. Thus, the wiring may go back and forth within the circuit, thereby increasing the wiring length.

Therefore, it is more preferable to perform the procedure shown in FIG. 17, which is the procedure of FIG. 16 with additional steps, i.e. the arranging step 703 and the chain connecting step 704. In the procedure of FIG. 17, in each circuit 500 where the chain connecting step 702 has been completed, considering the arranged positions, the input part of the BI control signal 400, the control signal input terminals (C) 302 of each circuit 500, and the BI control signal output terminals (SO) 501 of each circuit 500 are reconnected in accordance with the coordinates of the circuit arrangements. Thereby, an increase in the wiring length can be prevented.

First, in the clock control circuit finding step 700, the clock control circuit replacing step 701, and the chain-connecting step 702, each step is performed in the same manner as that of FIG. 16. Then, in the arranging step 703, the arranging positions are determined by disposing each circuit 500 in accordance with the coordinates of the circuit arrangement. Next, in the chain-reconnecting step 704, there is found the clock control circuit 500 with BI control signal input/output terminal (referred to as a first circuit) having the BI control signal input terminal (C) 302 that is closest, in terms of the position, to the input part of the BI control signal of the semiconductor integrated circuit, and the BI control signal input terminal (C) 302 of the found first circuit 500 is connected to the input part of the BI control signal of the semiconductor integrated circuit. Further, there is found the clock control circuit 500 with BI control signal input/output terminal (referred to as a second circuit) having the control signal input terminal (C) 302 that is closest, in terms of the position, to the BI control signal output terminal (SO) 501 of the first circuit 500, and the BI control signal input terminal (C) 302 of the found second circuit 500 is connected to the BI control signal output terminal (SO) 501 of the first circuit 500 described above. Furthermore, there is found the clock control circuit 500 with BI control signal input/output terminal (referred to as a third circuit) having the BI control signal input terminal (C) 302 that is closest, in terms of the position, to the BI control signal output terminal (SO) 501 of the second circuit 500, and the BI control signal input terminal (C) 302 of the found third circuit 500 is connected to the BI control signal output terminal (SO) 501 of the second circuit 500 described above.

By repeating the step 704 described above, the input part of the BI control signal 400 of the semiconductor integrated circuit, the control signal input terminals (C) 302 of each clock control circuit 500 with BI control signal input/output terminal, and the BI control signal output terminals (SO) 501 can be reconnected via the shortest route.

In the semiconductor integrated circuit and the semiconductor integrated circuit manufacturing method constituted as described above, the clock control circuits 500 with BI control signal input/output terminal are disposed on the clock circuit and, then, the input part of the BI control signal 400, the BI control signal input terminals (C) 302 of each clock control circuit 500 with BI control signal input/output terminal, and the BI control signal output terminals (SO) 501 are connected to each other (chain connection) to have the shortest connecting route. With this, all the transistors can be advance-deteriorated without increasing the processing time and the wiring. In addition, it is possible to decrease congestion of the wiring in the BI control signal wiring 406 and the length of the wiring.

The described structure of the clock control circuit 500 with BI control signal input/output terminal is merely an example. As shown in FIG. 9 of the first embodiment, it may be structured in such a manner that a plurality of BI control signal input terminals are provided, in which the value of output from the clock control signal output terminal (Z) may be set elective from high potential, low potential, and output of the clock signal waveform. Furthermore, it may be structured as the clock control circuit with BI control signal input/output terminal, which performs only one of those actions.

The buffer circuit 502 is used for connecting between the BI control signal input terminals (C) 302 of the clock control circuit 500 with BI control signal input/output terminal and the BI control signal output terminals (SO) 501. However, the inverter circuit may be used instead and the logic is inverted for being propagated.

That is, when the following conditions are satisfied;
there are both the rise signal action flip-flop and the fall signal action flip-flop present in the clock circuit
there is the clock control circuit 500 with BI control signal input/output terminal, which outputs the signal appropriate for advance-deterioration of the fall signal action flip-flop by setting the BI control signal input terminal (C) 302 as low potential,
   the BI control signal 400 becomes the signal appropriate for advance-deterioration of the rise signal action flip-flop. However, it is not the signal appropriate for the advance-deterioration of the fall signal action flip-flop partially present in the circuit.

In such case, for making the BI control signal appropriate for the advance-deterioration of the fall signal action flip-flop, the logic of signal propagated from the BI control signal input terminal (C) 302 to the BI control signal output terminal (SO) 501 may be inverted by the inverter circuit. With this, all the rise signal action flip-flops and the fall signal action flip-flops on the clock circuit can be advance-deteriorated.

In FIG. 15, the BI control signal wiring 406 is connected in the sate of a single chain (series connection). However, the present invention is not limited to be connected in a chain form. In other words, like the BI control signal branch wiring 406 shown in FIG. 18, there may also provide the branch-connection state in a part of the chain connection.

Further, the clock control circuits 500 with BI control signal input/output terminal (FIG. 11) and the clock control circuits 304 with BI control signal input terminal (FIG. 5) may both be provided within the clock circuit.

Furthermore, in the connecting method described by referring to FIG. 16 and FIG. 17, the clock control circuits are replaced with the clock control circuits 500 with BI control signal input/output terminal in the clock control circuit finding step 700 and the clock control circuit replacing step 701. However, the clock control circuits 500 with BI control signal input/output terminal may be disposed in the first place at the time of making a net list.

Moreover, the output part 600 of the BI control signal shown in FIG. 15 and FIG. 18 may not have to be provided when propagation of the BI control signal to the next block is unnecessary.

### THIRD EMBODIMENT

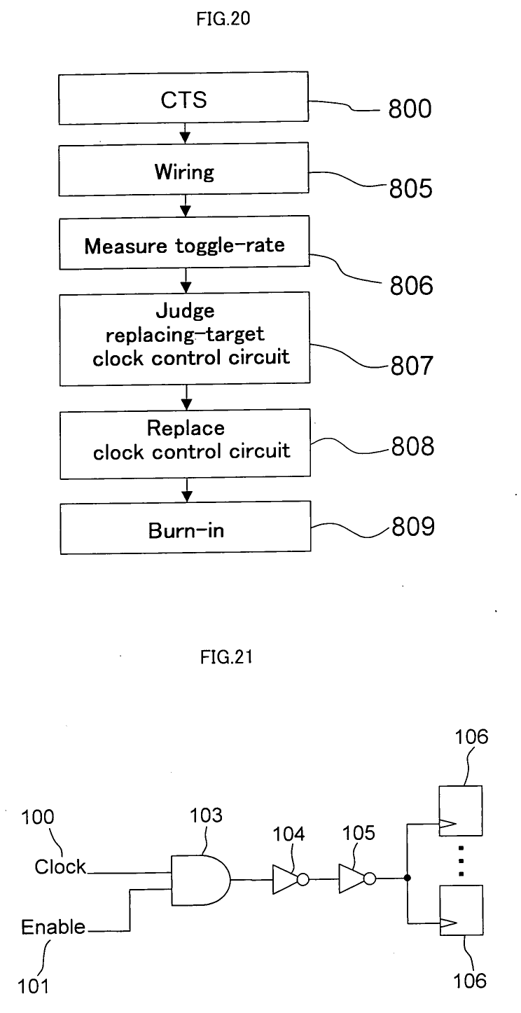

A third embodiment of the present invention will be described by referring to FIG. 19 and FIG. 20. FIG. 19 and FIG. 20 are flowcharts for describing a manufacturing method of the clock circuit that comprises a control circuit with BI control signal in a part thereof.

In FIG. 19, reference numeral 800 is a CTS step, 801 is a toggle-rate measuring step, 802 is a replacing-target clock control circuit judging step, 803 is a clock control circuit replacing step, and 804 is a burn-in step. In FIG. 20, reference numeral 805 is a wiring step, 806 is a toggle-rate measuring step, 807 is a replacing-target clock control circuit judging step, 808 is a clock control circuit replacing step, and 809 is a burn-in step.

The manufacturing method illustrated in FIG. 19 will be described. For designing the clock circuit shown in FIG. 10, in order to reduce the clock-signal reaching-time difference (referred to as clock skew hereinafter) to the flip-flops, there requires clock tree synthesis (referred to as CTS hereinafter) for adjusting the clock skew using the buffer, inverter, and the like. However, when CTS is performed, a great number of buffers or inverters, etc. are inserted to the clock circuit. Thus, it is important to perform CTS in advance for measuring the toggle rate of the clock circuit. Therefore, prior to all the steps, the CTS step 800 is performed.

Then, simulations for each operation modes are carried out on the circuit that has completed the CTS step 800 so as to measure the operation rate of the clock circuit. Then the toggle-rate measuring step 801 is performed. By measuring the toggle rate, the mode with the highest operating rate (referred to as a first operation mode hereinafter) is judged.

Next, in the replacing-target clock control circuit judging step 802, there is obtained information regarding the clock control circuit that does not operate at the time of the first operation mode and information regarding the clock control circuit where the clock signal is fixed by the clock control signal.

Based on the result of the step 802, in the clock control circuit replacing step 803, only the clock control circuit where the signal is fixed under the first operation mode is replaced with the clock control 304 circuit with BI control signal input terminal or the clock control circuit 500 with BI control signal input/output terminal. By designing the clock control circuits 304 with BI control signal input terminal and the clock control circuits 500 with BI control signal input/output terminal to have the same delay value as that of the clock control circuit having no BI control input signal, generation of clock skew after the replacement can be prevented.

After completing the replacement in this manner, the BI processing is performed in the BI step 804. The BI mode when performing the BI processing is the BI mode that includes an operating condition of the first operation mode and an operating condition for outputting a desired signal from the clock control circuit 304 with BI control signal input terminal or the clock control circuit 500 with BI control signal input/output terminal.

Next, there is described the designing procedure shown in FIG. 20. As described in the designing procedure of FIG. 19, in the structure of the clock circuit shown in FIG. 10, the CTS step 800 is performed prior to all the steps.

Then, the wiring step 805 is performed considering the influence of the wiring congestion due to the use of the clock control circuits 304 with BI control signal input terminal or the clock control circuits 500 with BI control signal input/output terminal. In the wiring step 805, each of the circuits such as the AND circuit, buffer circuit, etc. are wired (connected by wiring) physically according to a connecting rule. After the wiring, the degree of wiring congestion is calculated. The degree of the wiring congestion can be calculated from the number of passing wirings per unit area, etc. for example.

Subsequently, as in FIG. 19, simulations for each operation mode are carried out on the circuit for measuring the operation rate of the clock circuit and, then, the toggle-rate measuring step 805 is performed. By performing the toggle-rate measuring step 805, there is determined an operation mode with the highest operation rate (referred to as a second operation mode) in the clock circuit that is in a section with lower degree of wiring congestion than other sections.

With the second operation mode detected in the toggle-rate measuring step 806, the replacing-target clock control circuit judging step 807 is performed. By the step 807, there is obtained information regarding the clock control circuit that does not operate and information regarding the clock control circuit where the clock signal is fixed by the clock control signal.

Based on the result of the step 807, in the clock control circuit replacing step 808, only the clock control circuit where the signal is fixed under the second operation mode is replaced with the clock control circuit 304 with BI control signal input terminal or the clock control circuit 500 with BI control signal input/output terminal. By designing the clock control circuit 304 with BI control signal input terminal and the clock control circuit 500 with BI control signal input/output terminal to have the same delay value as that of the clock control circuit having no BI control input signal, generation of clock skew after replacement of the circuits can be prevented.

After completing the replacement in this manner, the BI processing is performed in the BI step 809. The BI mode when performing the BI processing is the BI mode that includes an operating condition of the second operation mode and an operating condition for outputting a desired signal from the clock control circuit 304 with BI control signal input terminal or the clock control circuit 500 with BI control signal input/output terminal.

The semiconductor integrated circuit manufacturing method structured as described above enables the following effects. With the manufacturing procedure shown in FIG. 19, the area can be reduced compared to the case where all the clock control circuits in the clock circuit are replaced with the clock control circuits 304 with BI control signal input terminal or the clock control circuits 500 with BI control signal input/output terminal. Furthermore, with the manufacturing procedure shown in FIG. 20, in addition to reducing the area, the wiring congestion can be reduced compared to the case where all the clock control circuits in the clock circuit are replaced with the clock control circuits 304 with BI control signal input terminal or the clock control circuits 500 with BI control signal input/output terminal.

The wiring of the BI control signal may be chain-connected (includes the case with branches) as shown in FIG. 15 and FIG. 18. Further, the chain may be reconnected based on the arrangement information.

### FOURTH EMBODIMENT

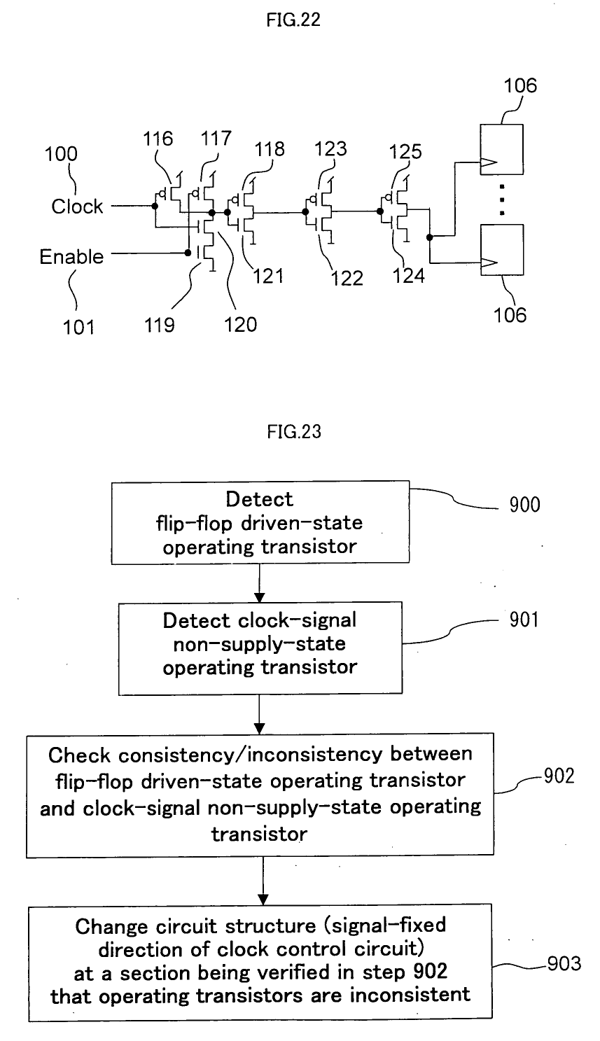

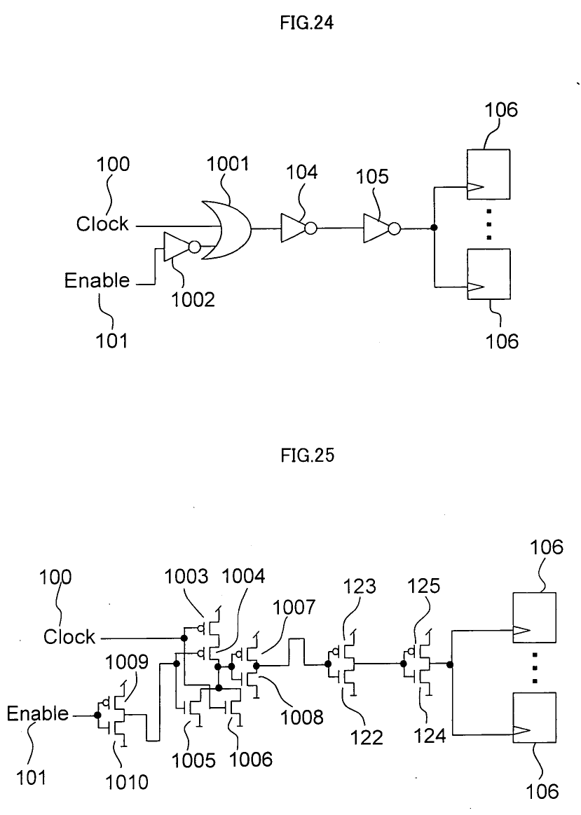

A fourth embodiment of the present invention will be described by referring to FIG. 21-FIG. 25. The same reference numerals are applied to the same structural elements as those of the first embodiment, and the description thereof will be omitted. FIG. 21 is a block diagram for showing an example the clock circuit that comprises the clock control circuits with BI control signal input terminal. FIG. 22 is block diagram (circuit diagram) of conventional transistors which achieve the clock control circuit of FIG. 21. FIG. 23 is a flowchart for showing the procedure of changing the clock control circuit. FIG. 24 is a block diagram for showing the structure of the clock circuit according to the embodiment, which comprises the clock control circuits with BI control signal input terminal. FIG. 25 is a block diagram (circuit diagram) of conventional transistors which achieve the clock control circuit of FIG. 24.

When supply of the clock signal to the rise signal action flip-flop 106 is stopped in the structure of the clock circuit as shown in FIG. 21, by setting the clock control signal as low potential, the output of the AND circuit 103 is fixed as low, thereby stopping the action of the rise signal action flip-flop 106. As a result, the transistors 123 and 124 of FIG. 22 become the clock-signal non-supplied-state operating transistors.

In the meantime, at the time of supplying the clock signal to the rise signal action flip-flop 106, the clock signal is set as high potential so that the waveform of the clock signal 100 is propagated to the output signal of the AND circuit 103. As a result, the transistors 122 and 125 become the flip-flop driven-state operating transistors.

As described, the clock-signal non-supplied-state operating transistors, 123, 124 and the flip-flop driven-state operating transistors 122, 125 are different. Therefore, when the BI processing is performed under the state where supply of the clock signal to the AND circuit 103 is stopped, the flip-flop driven-state operating transistors 122, 125 cannot be advance-deteriorated. As a result, in the clock circuit to the rise signal action flip-flop 106, the transistors 122 and 125 may be advance-deteriorated when the clock circuit is in action after being on the market and the circuit may malfunction.

Thus, the structure of the clock control circuit is modified by the procedure shown in FIG. 23. In FIG. 23, step 900 is a step of detecting flip-flop driven-state operating transistor, step 901 is a step of detecting clock-signal non-supplied state operating transistor, step 902 is a step of detecting consistency of the operating transistors detected in the steps 900 and 901, step 903 is a step of changing the signal fixed direction of the clock control circuit from the section where it is detected as inconsistent in the step 902.

The procedure shown in FIG. 23 is performed on the clock circuit of FIG. 21. In the step 900, the flip-flop driven-state operating transistors 122 and 125 are detected when the rise signal action flip-flop 106 is in action. In the clock circuit, the transistors inside the AND circuit 103 of the clock control circuit are eliminated from the detection target as the operating transistors.

In the step 901, the clock-signal non-supplied-state operating transistors, 123, 124 are detected when the output signal of the AND circuit 103 is fixed low and supply of the clock signal to the rise signal action flip-flop 106 is stopped. In the clock circuit, the transistors inside the AND circuit 103 of the clock control circuit are eliminated form the detection target as the operating transistors.

In the step 902, it is detected that the clock-signal non-supplied-state operating transistors, 123, 124 and the flip-flop driven-state operating transistors 122, 125 are different.

In the step 903, in order to change the signal fixed direction of the clock control circuit (AND circuit 103) from low potential to high potential, the circuit structure is modified in such manner that the AND circuit 103 is changed to the OR circuit and, at the same time, the inverter circuit is inserted between the AND circuit 103 and the input part of the clock control signal.

FIG. 24 shows the clock circuit to which the modification of the circuit structure in the step 903 has been performed. In FIG. 24, reference numeral 1001 is the OR circuit and 1002 is the inverter circuit. FIG. 25 is an illustration showing the OR circuit 1001 and the inverter circuit 1002 with transistors, in which 1003-1008 are the transistors constituting the OR circuit 1001, and 1009, 1010 are the transistors constituting the inverter circuit 1002, respectively.

By the modification of the circuit structure performed in the step 903, as shown in FIG. 25, the transistors 122 and 125 also function as the clock-signal non-supply-state operating transistors when supply of the clock signal is stopped. Therefore, the transistors are consistent with the flip-flop driven-state operating transistors.

With the semiconductor integrated circuit and the semiconductor integrated circuit manufacturing method constituted as described above, the flip-flop driven-state operating transistors can be advance-deteriorated even if the BI processing is performed under the state where supply of the clock signal is stopped. Therefore, all the transistors can be advance-deteriorated without increasing the processing time and the wirings.

### FIFTH EMBODIMENT

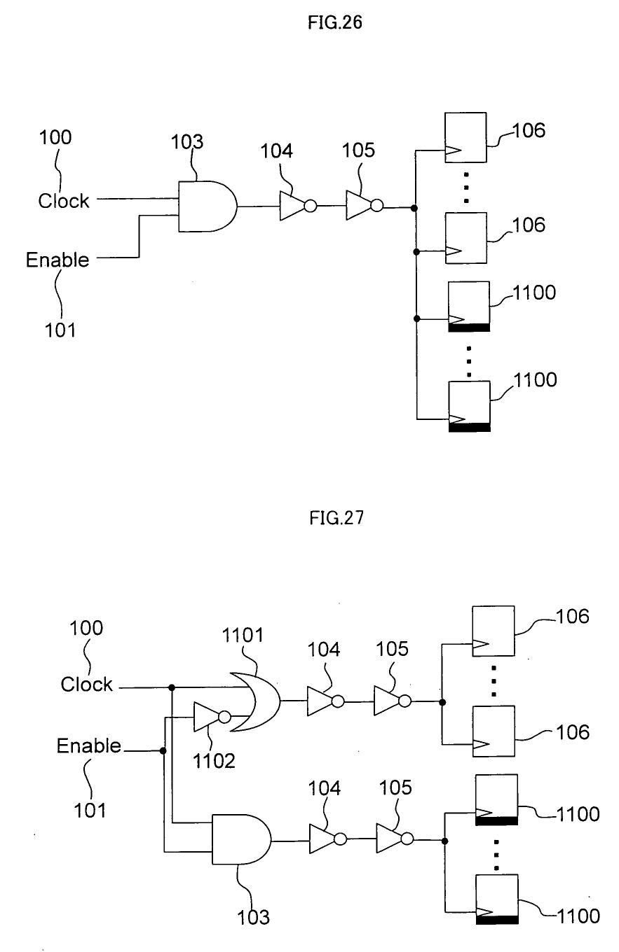

A fifth embodiment of the present invention will be described by referring to FIG. 26 and FIG. 27. The same reference numerals are applied to the same structural elements as those of the first embodiment, and the description thereof will be omitted.

FIG. 26 is a block diagram for showing an example the clock circuit that comprises the clock control circuits with BI control signal input terminal. FIG. 27 is a block diagram (circuit diagram) of conventional transistors which achieve the clock control circuit of FIG. 26. In FIG. 26, reference numeral 1100 is the fall signal action flip-flop. In FIG. 27, 1101 is the OR circuit and 1102 is the inverter circuit.

In the clock circuit of FIG. 26, by setting the clock control signal 101 as low potential under the state where supply of the clock signal to the rise signal action flip-flop 106 is stopped, the output signal of the AND circuit 103 becomes low potential, thereby stopping the action of the rise signal action flip-flop 106.

In FIG. 26, the clock-signal non-supplied-state operating transistors are different from the flip-flop driven-state operating transistors, however, consistent with the flip-flop driven-state operating transistors of the fall signal action flip-flop 1100.

Under the state where both the rise signal action flip-flop 106 and the fall signal action flip-flop 1100 are present as described above, the following modifications of the circuit may be performed (see the fourth embodiment) in order to make the clock-signal non-supplied-state operating transistors be consistent with the flip-flop driven-state operating transistors:
the circuit is modified such that the rise signal action flip-flop is signal-fixed as high potential; and further,
the circuit is modified such that the fall signal action flip-flop is signal-fixed as low potential.

Thus, in the step 903 of the method for modifying the clock control circuit illustrated in FIG. 23, the following modifications of the circuit are performed:
the rise signal action flip-flop is signal-fixed as high potential; and
the fall signal action flip-flop is signal-fixed as low potential.

The above-described modifications can be easily achieved by performing: the processing of discriminating the rise signal action flip-flop and the fall signal action flip-flop; and the processing of modifying the clock control circuit to the circuit structure that can fix the signal as high potential and to the circuit structure that can fix the signal as low potential in accordance with the action state of the discriminated flip-flop.

Specifically, as shown in FIG. 27, the clock control circuit connected to the rise signal action flip-flop 106 is changed to the OR circuit 1101 to which the clock signal 100 is inputted and the clock control signal 101 is inputted through the inverter circuit 1102. The clock control circuit connected to the fall signal action flip-flop 1100 is changed to the AND circuit 103 to which the clock signal 100 and the clock control signal 101 are inputted, respectively.

With the semiconductor integrated circuit manufacturing method constituted as described above, it is possible to advance-deteriorate the flip-flop driven-state operating transistors by the BI processing under the clock-signal non-supplied state, even if there both exist, simultaneously, the transistors (the flip-flop driven-state transistors and the like of the rise signal action flip-flop 106), which are different from the clock-signal non-supplied-state operating transistors, and the transistors (the flip-flop drive-state transistors and the like of the fall signal action flip-flop 1100), which are consistent with the clock-signal non-supplied-state operating transistors. In addition, all the transistors can be advance-deteriorated without increasing the processing time and the wirings.

### SIXTH EMBODIMENT

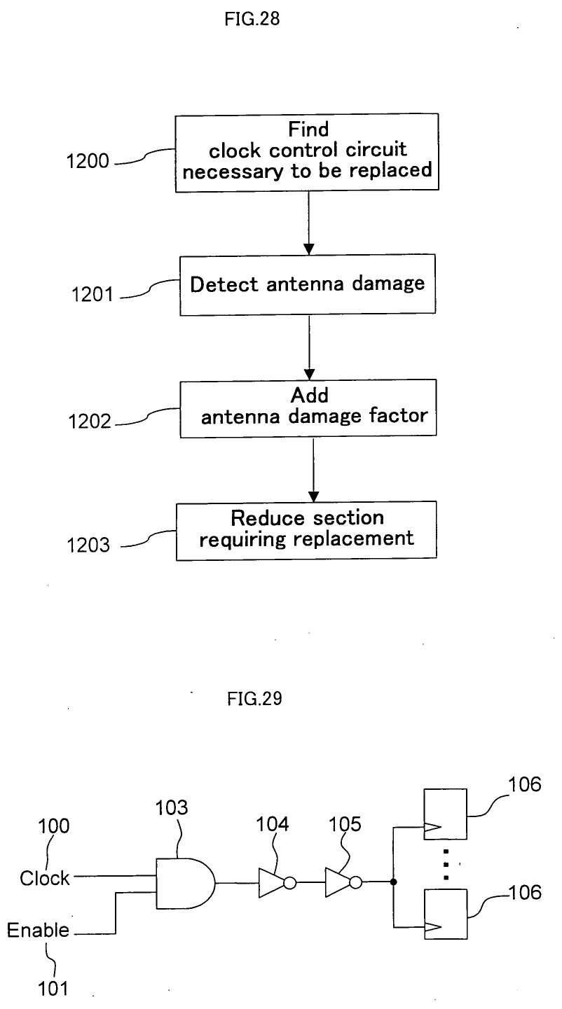

A sixth embodiment of the present invention will be described by referring to FIG. 28-FIG. 32. The same reference numerals are applied to the same structural elements as those of the first embodiment, and the description thereof will be omitted.

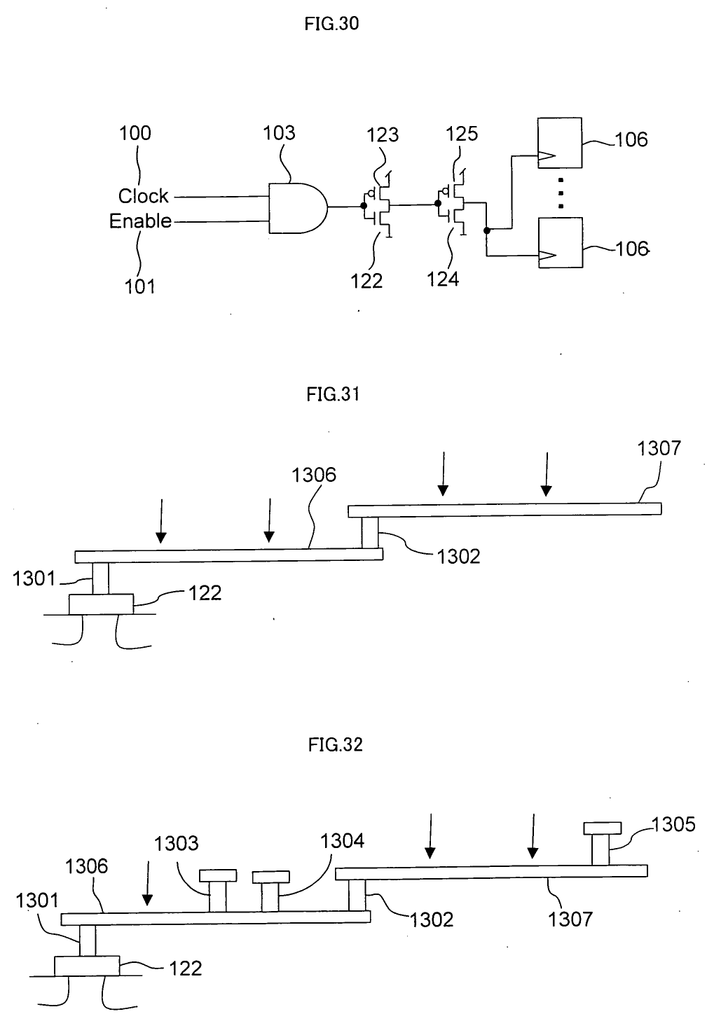

FIG. 28 is a flowchart for illustrating the procedure of a method for reducing the sections that require replacement. FIG. 29 is a block diagram for showing an example of the clock circuit that comprises the clock control circuits with BI control signal input terminal. FIG. 30 is a block diagram of the transistors within the clock circuit shown in FIG. 29. FIG. 31 and FIG. 32 are illustrations for describing the antenna damages of the transistors.

In FIG. 28, reference numeral 1200 is a step of finding the clock control circuit that requires replacement, 1201 is an antenna damage detecting step, 1202 is a step of adding antenna damaging factor, and 1203 is a step of eliminating the sections that require replacement, respectively. In FIG. 31 and FIG. 32, reference numerals 1301-1305 are vias, and 1306 and 1307 are wirings.

In the manufacturing step of the via and the metal wiring, there is required the processing using plasma such as dry etching. For example, when forming the via in an insulating layer, the via and the meal wiring are formed by: adding a resist film on the insulating layer for masking the part other than the via part; eliminating the insulating film of the via part through dry etching, and plasma-injecting a conductive material to the eliminated part. Wiring can be formed through the same processing.

Plasma is used in this step of forming the via and the wiring. However, when the via and the wiring are not connected to a diffusion layer, plasma charges are accumulated in the via and the wiring, and electric current flows into a gate oxide film of the connected transistor. By the electric current flown in this way, there are caused malfunctions such as breakdown of the gate oxide film, changes in the transistor property due to the change in the film quality of the gate oxide film and, furthermore, deterioration in the life of hot-carrier.

Such phenomenon is called “antenna effect”. In general, the malfunction such as the breakdown of the gate oxide film is prevented by setting the antenna effect as a specific value or less. Hereinafter, damage to the gate due to the antenna effect is referred to as “antenna damage”.

However, the state where the electric current is flown into the gate oxide film of the transistor due to the plasma charge is the same as the state where the gate of the transistor is ON. In additions, the plasma processing is performed at high temperatures. Taking such characteristic of the plasma processing into account, by accumulating the proper amount of the plasma charge in the gate oxide film (giving antenna damage) through the plasma processing, it is possible to obtain the same effect (advance-deterioration) as that of aging deterioration of the transistors obtained by the BI processing. Therefore, it becomes unnecessary to perform the advance-deterioration processing by the BI processing for the transistor with the proper value of antenna damage.

Thus, in the embodiment, the amount of the antenna damage in the transistor that requires the advance-deterioration processing is appropriately corrected so that the antenna damage equivalent to the advance-deterioration processing is supplied to the via and the wiring. Thereby, the advance-deterioration becomes unnecessary. The amount of the antenna damage can be easily calculated from the number and shape of the vias, the wiring layer, the wiring pattern, the plasma-processing time, etc.

In the embodiment, the above-described processing is performed by the procedure shown in FIG. 28. Specifically, first, in the step 1200, there is found the clock control circuit being judged as necessary to be replaced, as in the step 700 in the procedure illustrated in FIG. 16 and FIG. 17. In the clock circuit of FIG. 29, the potential of the clock control circuit (AND circuit 103) when supply of the clock signal is stopped is low. As can be seen from this, in this clock circuit, the operating transistors differ between the case where the supply of the clock signal is stopped and the case where the flip-flop is in action. Therefore, in this clock circuit, it is necessary to replace the AND circuit 103 with a special cell that is capable of causing antenna damage (advance-deterioration). In the step 1200, there is found such circuit structure (AND circuit 103, etc).

In the step 1201, the amounts of the antenna damage to the flip-flop driven-state operating transistors 122 and 125 are detected. In the embodiment, it is assumed that the antenna damage of the transistor 125 is within the proper range for the advance-deterioration and the antenna damage of the transistor 122 is less than the proper value.

In the step 1202, redundant via is inserted to the wiring connected to the transistor 122 that is detected in the step 1201 as having the antenna damage of less than the proper value until the value reaches the proper value as the advance-deterioration.

In the step 1203, if all the operating transistors after the clock control circuit come to have the proper-value antenna damage through the processing till the step 1202, those are eliminated from the target of replacing processing. For the operating transistors as the target of the replacing processing, there is performed one of the replacing processing illustrated in the first to fifth embodiment described above. With this, it is possible in this embodiment to reduce, preferably, eliminate the replacing sections of the clock control circuit completely.

FIG. 31 shows the transistor 122 part of the clock circuit shown in FIG. 30. FIG. 32 illustrates the state where redundant vias 1303-1305 are inserted to the wiring that is connected to the transistor 122 having the antenna damage of less than the proper value.

In the semiconductor integrated circuit and the semiconductor integrated circuit manufacturing method constituted as described above, all the transistors can be advance-deteriorated without increasing the processing time and the wirings by correcting the antenna damage of the clock control circuit to be the proper value for the advance-deterioration. In addition, it is possible to reduce the number of the clock control circuits to be replaced, which enables reduction in the cell area and congestion of the wiring.

In the embodiment, the antenna damage is increased by inserting the redundant via as the additional factor for the antenna damage. However, the same effects can be achieved also by adding the redundant wiring.

The present invention has been described in detail by referring to the most preferred embodiments. However, various combinations and modifications of the components are possible without departing from the sprit and the broad scope of the appended claims.

What is claimed is:

1. A semiconductor integrated circuit, comprising a clock circuit for generating a clock signal, wherein
said clock circuit comprises a clock control circuit for controlling propagation of said clock signal, wherein
said clock control circuit comprises:
a burn-in control signal input terminal to which a burn-in control signal that controls operation state of said clock circuit when performing burn-in processing is inputted; and
a clock control signal output terminal for outputting said clock signal, wherein
said clock control circuit controls propagation of said clock signal outputted from said clock control signal output terminal based on said burn-in control signal inputted to said burn-in control signal input terminal.

2. The semiconductor integrated circuit according to claim 1, wherein said clock control circuit controls either potential or waveform of said clock signal outputted from said clock control signal output terminal based on said burn-in control signal inputted to said burn-in control signal input terminal.

3. The semiconductor integrated circuit according to claim 1, wherein said clock control circuit comprises a burn-in control signal output terminal for outputting said burn-in control signal.

4. The semiconductor integrated circuit according to claim 3, wherein said burn-in control signal inputted to said burn-in control signal input terminal is outputted from said burn-in control signal output terminal in a same or changed logic.

5. The semiconductor integrated circuit according to claim 3, comprising a plurality of said clock control circuits, wherein
said burn-in control signal output terminal of one of said plurality of clock control circuits is connected to said burn-in control signal input terminal of another circuit, and the connection is repeated between said plurality of clock control circuits so as to connect said plurality of clock control circuits successively.

6. The semiconductor integrated circuit according to claim 5, wherein, there are both a group of circuits connected in series and a group of circuits connected in parallel present in said plurality of clock control circuits connected successively.

7. A semiconductor integrated circuit manufacturing method, comprising the steps of:
preparing a plurality of clock control circuits which comprise a burn-in control signal input terminal to which a burn-in control signal that controls operation state when performing burn-in processing is inputted, and a burn-in control signal output terminal for outputting said burn-in control signal; and
connecting said plurality of clock control circuits successively on a circuit by repeating processing, which is to connect said burn-in control signal output terminal of one of said plurality of clock control circuits to said burn-in control signal input terminal of another circuit.

8. The semiconductor integrated circuit manufacturing method according to claim 7, further comprising the step of:
performing burn-in processing on a manufactured semiconductor integrated circuit after controlling operating state of transistors constituting said semiconductor integrated circuit to be suited for said burn-in processing by inputting said burn-in control signal to said manufactured semiconductor integrated circuit through said burn-in control signal input terminal.

9. A semiconductor integrated circuit manufacturing method, comprising the steps of:
designing a semiconductor integrated circuit which comprises a clock circuit with a clock control circuit;
finding said clock control circuit in said semiconductor integrated circuit being designed; and replacing said clock control circuit being found with a clock control circuit with a burn-in control signal input terminal.

10. The semiconductor integrated circuit manufacturing method according to claim 9, further comprising the step of:
performing burn-in processing on manufactured said semiconductor integrated circuit after controlling operating state of transistors constituting said semiconductor integrated circuit to be suited for said burn-in processing by inputting said burn-in control signal to said semiconductor integrated circuit through said burn-in control signal input terminal.

11. The semiconductor integrated circuit manufacturing method according to claim 7, further comprising the steps of:
setting a burn-in control signal input part in a semiconductor integrated circuit and arranging said plurality of clock control circuits connected successively on said semiconductor integrated circuit; and
repeating reconnection processing where: among said clock control circuits, said burn-in control signal input terminal of a first clock control circuit, which comprises said burn-in control signal input terminal closest, in terms of position, to said burn-in control signal input part, is reconnected to said burn-in control signal input part; said burn-in control signal input terminal of a second clock control circuit, which comprises said burn-in control signal input terminal closest, in terms of position, to said burn-in control signal output terminal of said first clock control circuit, is reconnected to said burn-in control output terminal of said first clock control circuit; and said burn-in control signal input terminal of a third clock control circuit, which comprises said burn-in control signal input terminal closest, in terms of position, to said burn-in control signal output terminal of said second clock control circuit, is reconnected to said burn-in control signal output terminal of said second clock control circuit.

12. A semiconductor integrated circuit manufacturing method, comprising the steps of:
wiring a clock circuit which comprises a clock control circuit with no burn-in control signal input terminal;
judging an operation mode with highest operation rate by measuring operation rate of said clock circuit being wired;
judging a clock control circuit whose signal is fixed in said operation mode with said highest operation rate; and
replacing, with a clock control circuit having said burn-in control signal input terminal, said clock control circuit whose signal is fixed in said operation mode with said highest operation rate.

13. The semiconductor integrated circuit manufacturing method according to claim 12, further comprising the step of:
performing burn-in processing on a manufactured semiconductor integrated circuit after controlling operating state of transistors constituting said semiconductor integrated circuit to be suited for said burn-in processing by inputting said burn-in control signal to said semiconductor integrated circuit through said burn-in control signal input terminal.

14. A semiconductor integrated circuit manufacturing method, comprising the steps of:
wiring a clock circuit which comprises a clock control circuit with no burn-in control signal input terminal;
judging an operation mode with highest operation rate in a section where wiring congestion degree is lower than other sections, by measuring operation rate of said clock circuit after specifying said section where said wiring congestion degree is lower than other sections in said clock circuit;
judging a clock control circuit whose signal is fixed in said operation mode with said highest operation rate in said section where said wiring congestion degree is lower than said other sections; and
replacing, with a clock control circuit having said burn-in control signal input terminal, said clock control circuit whose signal is fixed in said operation mode with said highest operation rate in said section where said wiring congestion degree is lower than said other sections.

15. The semiconductor integrated circuit manufacturing method according to claim 14, further comprising the step of:
performing burn-in processing on a manufactured semiconductor integrated circuit after controlling operating state of transistors constituting said semiconductor integrated circuit to be suited for said burn-in processing by inputting said burn-in control signal to said manufactured semiconductor integrated circuit through said burn-in control signal input terminal.

16. A semiconductor integrated circuit manufacturing method, comprising the steps of:
wiring a clock circuit which comprises a clock control circuit for controlling propagation of a clock signal and includes transistors, and a flip-flop that is controlled by said clock signal;
detecting a transistor from said transistors, which operates under a flip-flop driven state;
detecting a transistor from said transistors, which operates under a clock-signal non-supplied state;
checking whether or not said transistor operating in said flip-flop driven state and said transistor operating in said clock-signal non-supplied state are consistent with each other; and
changing a signal-fixed direction of said clock control circuit at a section where it is confirmed that said transistor operating in said flip-flop driven state and said transistor operating in said clock-signal non-supplied state are inconsistent.

17. The semiconductor integrated circuit manufacturing method according to claim 16, further comprising the step of:
performing burn-in processing on a manufactured semiconductor integrated circuit after controlling operating state of transistors constituting said semiconductor integrated circuit to be suited for said burn-in processing by inputting said burn-in control signal to said semiconductor integrated circuit through said burn-in control signal input terminal.

18. A semiconductor integrated circuit, comprising:
a clock circuit which is constituted including transistors and generates a clock signal; and
a flip-flop controlled by said clock signal, wherein
said transistors operating in said flip-flop driven state and said transistor operating in said clock-signal non-supplied state are all consistent.

19. A semiconductor integrated circuit manufacturing method, comprising the steps of:
designing a semiconductor integrated circuit which comprises a clock circuit that has a clock control circuit and generates a clock signal, and flip-flops controlled by said clock signal;
discriminating said flip-flop that comes in an action state by said clock signal in one state, and said flip-flop that comes in an action state by said clock signal in another state; and
changing said clock control circuit within said clock circuit connected to said flip-flop to a clock control circuit that is appropriate for said action states of each of said flip-flops that are being discriminated.

20. The semiconductor integrated circuit manufacturing method according to claim 19, further comprising the step of:
performing burn-in processing on a manufactured semiconductor integrated circuit after controlling operating state of transistors constituting said semiconductor integrated circuit to be suited for said burn-in processing by inputting said burn-in control signal to said semiconductor integrated circuit through said burn-in control signal input terminal.

21. A semiconductor integrated circuit manufacturing method, comprising the steps of:
designing a semiconductor integrated circuit which comprises a clock circuit with clock control circuits;
finding said clock control circuits on said semiconductor integrated circuit that is being designed;
detecting antenna damage amount of said clock control circuit that is being found, and
replacing, with a clock control circuit having a burn-in control signal input terminal, a remaining clock control circuit after eliminating a clock control circuit where said antenna damage being detected is equivalent to a damage by burn-in processing.

22. The semiconductor integrated circuit manufacturing method according to claim 21, further comprising the step of:
performing burn-in processing on a manufactured semiconductor integrated circuit after controlling operating state of transistors constituting said semiconductor integrated circuit to be suited for said burn-in processing by inputting said burn-in control signal to said semiconductor integrated circuit through said burn-in control signal input terminal.

23. The semiconductor integrated circuit manufacturing method according to claim 21, further comprising the step of:
to said clock control circuit having detected said antenna damage smaller than said damage by said burn-in processing, adding an antenna damage factor for making said antenna damage of said circuit equivalent to said damage by said burn-in processing, wherein
a clock control circuit, in which said antenna damage of said circuit does not become equivalent to said damage by said burn-in processing even after adding said antenna damage factor, is replaced with said clock control circuit having said burn-in control signal input terminal.

24. A semiconductor integrated circuit produced by said semiconductor integrated circuit manufacturing method according to claim 21, comprising an additional factor for antenna damage.
